(19) United States
(12) Patent Application Publication
(10) Pub. No.: US 2015/0137858 A1
(43) Pub. Date: May 21, 2015

(54) BUFFER CIRCUIT

(71) Applicant: Kabushiki Kaisha Toshiba, Minato-ku (JP)

(72) Inventors: Tetsuro ITAKURA, Nerima (JP); Masanori Furuta, Odawara (JP); Shunsuke Kimura, Kawasaki (JP); Go Kawata, Kawasaki (JP); Hideyuki Funaki, Shinagawa (JP)

(73) Assignee: Kabushiki Kaisha Toshiba, Minato-ku (JP)

(21) Appl. No.: 14/540,059

(22) Filed: Nov. 13, 2014

(30) Foreign Application Priority Data
Nov. 19, 2013 (JP) 2013-239202

(51) Int. Cl. H03K 3/012

(52) U.S. Cl. CPC H03K 3/012
USPC 327/109

(57) ABSTRACT

In one embodiment, a buffer circuit includes a first transistor, a second transistor, a first current source, a third transistor, a fourth transistor, a second current source, and a third current source. The first transistor has a control terminal connected to an input terminal, and a first terminal connected to an output terminal. The second transistor has a control terminal connected to the input terminal, a first terminal connected to the output terminal, and a second terminal connected to a first power source. The third transistor has a first terminal connected to the output terminal. The fourth transistor has a first terminal connected to the second terminal of the first transistor, a control terminal applied bias voltage, and a second terminal connected to a control terminal of the third transistor.

### CROSS REFERENCE TO RELATED APPLICATION(S)

This application is based upon and claims the benefit of priority from the prior Japanese Patent Application No. 2013-239202, filed on Nov. 19, 2013, the entire contents of which are incorporated herein by reference.

### FIELD

Embodiments described herein relate generally to a buffer circuit.

### BACKGROUND

Conventionally, a source follower circuit is widely used as a buffer circuit. However, in the source follower circuit, there is a problem in which current driving capability is restricted by current of a bias current source connected to a source terminal. To solve this problem, there is a proposed source follower circuit in which input voltage is applied to a gate terminal of each of two transistors connected in parallel, and in the case where drain current at one of the transistors is decreased, the current of the bias current source is controlled. However, in such a source follower circuit, there is a problem in which power consumption is increased because it is necessary to increase bias current in order to improve the current driving capability.

Additionally, there is another proposed source follower circuit in which the drain current of the transistor constituting the source follower circuit is compared with constant current, and this comparison result is converted to voltage such that the bias current is controlled using this voltage. However, in this source follower circuit, there is a problem in which the current driving capability is restricted by the constant current to be compared with the drain current of the transistor.

Further, according to the above-described source follower circuits in the related arts, there are times when operation becomes unstable due to influence of phase lag caused by parasitic capacitance of the transistor. For instance, according to the source follower circuits in the related arts, a peak is generated in frequency characteristic, thereby causing ringing in output voltage.

### BRIEF DESCRIPTION OF THE DRAWINGS

FIG. 1 is a circuit diagram illustrating a buffer circuit according to a first embodiment;

FIG. 2 is a diagram illustrating a simulation result of a transient analysis for the buffer circuit in FIG. 1;

FIG. 3 is a diagram illustrating a simulation result of an AC analysis for the buffer circuit in FIG. 1;

FIG. 4 is a circuit diagram illustrating the buffer circuit in FIG. 1 provided with phase compensation capacitor;

FIG. 5 is a diagram illustrating a simulation result of the transient analysis for the buffer circuit in FIG. 4;

FIG. 6 is a circuit diagram illustrating a buffer circuit according to a second embodiment;

FIG. 7 is a diagram illustrating a simulation result of the transient analysis for the buffer circuit in FIG. 6;

FIG. 8 is a diagram illustrating a simulation result of the AC analysis for the buffer circuit in FIG. 6;

FIG. 9 is a circuit diagram illustrating a buffer circuit according to a third embodiment;

FIG. 10 is a diagram illustrating a simulation result of the transient analysis for the buffer circuit in FIG. 9;

FIG. 11 is a circuit diagram illustrating the buffer circuit in FIG. 9 provided with the phase compensation capacitor; and

FIG. 12 is a diagram illustrating a simulation result of the transient analysis for the buffer circuit in FIG. 11.

### DETAILED DESCRIPTION OF THE INVENTION

Embodiments will now be explained with reference to the accompanying drawings. The present invention is not limited to the embodiments.

In one embodiment, a buffer circuit includes a first transistor, a second transistor, a first current source, a third transistor, a fourth transistor, a second current source, and a third current source. The first transistor has a control terminal connected to an input terminal, and a first terminal connected to an output terminal. The second transistor has a control terminal connected to the input terminal, a first terminal connected to the output terminal, and a second terminal connected to a first power source. The first current source is connected between a second terminal of the first transistor and the first power source. The third transistor has a first terminal connected to the output terminal. The fourth transistor has a first terminal connected to the second terminal of the first transistor, a control terminal applied bias voltage, and a second terminal connected to a control terminal of the third transistor. The second current source is connected between the second terminal of the fourth transistor and a second power source. The third current source is connected to the output terminal.

The buffer circuit amplifies a signal input from the input terminal Input, and outputs the signal from the output terminal Output. In the following, a buffer circuit including a MOS transistor will be described, and the buffer circuit may be configured using a bipolar transistor. The MOS transistor described below can be substituted with the bipolar transistor, and further a source terminal is substituted with an emitter terminal, a drain terminal with a collector terminal, and a gate terminal with a base terminal, thereby achieving to form the buffer circuit by using the bipolar transistor.

Further, in the following, an embodiment mainly using an N-channel MOS transistor will be described, but it is also possible to configure the buffer circuit mainly using a P-channel MOS transistor or a PNP type bipolar transistor. The N-channel (P-channel) MOS transistor described below is substituted with the P-channel (N-channel) MOS transistor or the PNP type (NPN type) bipolar transistor, and a terminal connected to a ground (power source) is connected to the power source (ground), thereby achieving to configure the buffer circuit mainly using the P-channel MOS transistor or the PNP type bipolar transistor is mainly used.

### First Embodiment

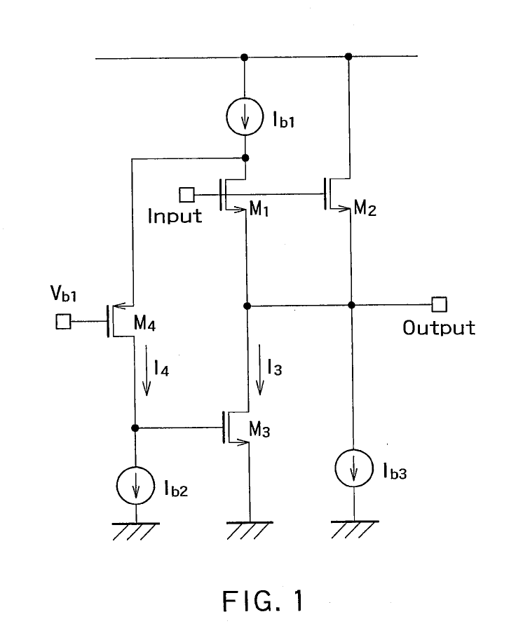

In the following, a buffer circuit according to a first embodiment will be described with reference to FIGS. 1 to 5. Here, FIG. 1 is a circuit diagram illustrating the buffer circuit according to the first embodiment. As illustrated in FIG. 1, the buffer circuit includes an input terminal Input, an output terminal Output, transistors M₁ to M₄, and current sources I_{b1} to I_{b3}.

A transistor M₁ (first transistor) is an N-channel MOS transistor (hereinafter referred to as “NMOS transistor”), having a gate terminal (control terminal) connected to the input terminal Input, a source terminal (first terminal) connected to the output terminal Output, and a drain terminal (second terminal) connected to the current source I_{b1}. In the transistor M₁, drain current I₁ corresponding to a difference between input voltage Vᵢₙ received from the input terminal Input and output voltage output from the output terminal Output flows.

The transistor M₂ (second transistor) is an NMOS transistor, having a gate terminal (control terminal) connected to the input terminal Input, a source terminal (first terminal) connected to the output terminal Output, and a drain terminal (second terminal) connected to a power source (first power source). In the transistor M₂, drain current I₂ corresponding to the difference between the input voltage Vᵢₙ received from the input terminal Input and the output voltage output from the output terminal Output flows.

The transistor M₃ (third transistor) is an NMOS transistor, having a gate terminal (control terminal) connected to a drain terminal of the transistor M₄, a source terminal connected to a ground (second power source), and a drain terminal (first terminal) connected to the output terminal Output. In the transistor M₃, drain current I₃ corresponding to the difference between the input voltage Vᵢₙ received from the input terminal Input and the output voltage output from the output terminal Output flows.

The transistor M₄ (fourth transistor) is a P-channel MOS transistor (hereinafter referred to as “PMOS transistor”), having a gate terminal (control terminal) from which bias voltage V_{b1} is applied, a source terminal (first terminal) connected to the drain terminal of the transistor M₁, and a drain terminal (second terminal) connected to the gate terminal of the transistor M₃. In the transistor M₄, drain current I₄ corresponding to a difference between current I_{b1} of the current source I_{b1} and the drain current I₁ flowing in the transistor M₁ (I₄=I_{b1}−I₁) flows.

The current source I_{b1} (first current source) is connected between a power source, the drain terminal of the transistor M₁, and the source terminal of the transistor M₄. The current source I_{b1} supplies bias current I_{b1} to the transistors M₁ and M₄.

The current source I_{b2} (second current source) is connected between a ground, the gate terminal of the transistor M₃, and the drain terminal of the transistor M₄. The current source I_{b2} supplies bias current I_{b2} to the transistor M₄. Note that the bias current I_{b1} and I_{b2} are set to be I_{b1}>I_{b2}.

The current source I_{b3} (third current source) is connected between the ground and the output terminal. The current source I_{b3} supplies bias current I_{b3} to the transistors M₁ and M₂.

Next, operation according to the present embodiment will be described. When the input voltage Vᵢₙ is received from the input terminal Input, Vₒᵤₜ amplified by a substantially single gain is output from the output terminal Output (Vᵢₙ≈Vₒᵤₜ). In the case where the input voltage Vᵢₙ is constant, the drain current becomes as next: I₄=I_{b2}, I₁=I_{b1}−I_{b2}. And, change of the current flowing in a current control circuit including the transistors M₁, M₃, and M₄ becomes small. In this case, operation of a source follower circuit including the transistor M₂ and the current source I_{b3} becomes dominant, thereby suppressing influence from the current control circuit to the operation of the buffer circuit. Therefore, the buffer circuit can be stably operated.

The state also becomes same in the case where the input voltage Vᵢₙ gradually changes, in which the drain current I₄ and I₁ become: I₄=I_{b2}, I₁=I_{b1}−I_{b2}, because the voltage at the source terminal of the transistor M₁ changes following the input voltage Vᵢₙ, namely, voltage change at the gate terminal of the transistor M₁. Therefore, the buffer circuit can be stably operated.

In contrast, in the case where the input voltage Vᵢₙ rapidly changes, the voltage at the source terminal of the transistor M₁ cannot instantaneously follow the change of the input voltage Vᵢₙ. For example, in the case where the input voltage Vᵢₙ rapidly rises, the voltage at the source terminal of the transistor M₁ cannot rise following the change of the input voltage Vᵢₙ, and therefore gate-source voltage at the transistor M₁ rises. Due to this, the drain current I₁ is increased, but restricted by the bias current I_{b1}. When the drain current I₁ is increased, the drain current I₄ is decreased (I₄<I_{b2}) because the drain current is: I₄=I_{b1}−I₁. When the drain current I₄ is decreased, the voltage at the drain terminal of the transistor M₄, namely, the voltage at the gate terminal of the transistor M₃ is decreased, and the drain current I₃ is decreased. The decreased drain current I₃ increases source current to the output terminal Output. In the case where the input voltage Vᵢₙ rapidly rises, it is possible to set such that the drain current at the transistor M₄ becomes zero. In this case, the drain current I₁ and I₄ become as next: I₁=I_{b1}, I₄=0. And, the drain current I₃ is more decreased and the source current to the output terminal Output is more increased. Further, large current can be supplied from the transistor M₂ to the output terminal Output because the drain current of the transistor M₂ is not restricted. Thus, in the case where the input voltage Vᵢₙ rapidly changes, the source current is increased and the voltage at the source terminal of each of the transistors M₂ and M₁, which is the output voltage, is increased following the input voltage V. When the change of the input voltage Vᵢₙ becomes small, rise of the input voltage Vᵢₙ becomes gradual and the voltage at the source terminal of the transistor M₁ rises following the change of the input voltage Vᵢₙ. Due to this, the current control circuit operates such that the drain current I₄ becomes: I₄=I_{b2}.

Additionally, in the case where the input voltage Vᵢₙ rapidly falls, the voltage at the source terminal in each of the transistors M₁ and M₂ cannot fall following the change of the input voltage Vᵢₙ, and therefore the gate-source voltage at the transistors M₁ and M₂ falls. Due to this, the drain current I₁ and the drain current I₂ are decreased. When the drain current I₁ is decreased, the drain current I₄ is increased (I₄>I_{b2}) because the drain current is: I₄=I_{b1}−I₁. When the drain current I₄ is increased, the voltage at the drain terminal of the transistor M₄, namely, the voltage at the gate terminal of the transistor M₃ rises, and the drain current I₃ is increased. The increased drain current I₃ increases sink current from the output terminal Output. In the case where the input voltage Vᵢₙ rapidly falls, it is possible to set such that the transistor M₁ is turned OFF. In this case, the drain current I₄ and I₁ become: I₄=I_{b1}, I₁=0. And, the drain current I₃ is more increased, and the sink current from the output terminal Output is increased. When the change of the input voltage Vᵢₙ becomes small, the falling of the input voltage Vᵢₙ becomes gradual, and the voltage at the source terminal of the transistor M₁ falls following the change of the input voltage Vᵢₙ. Due to this, the current control circuit operates such that the drain current I₄ becomes: I₄=I_{b2}.

As described above, according to the present embodiment, current driving capability can be improved by increasing the source current and the sink current of the output terminal Output by the current control circuit including the transistors M₁, M₃, and M₄. Further, in the case where the input voltage Vᵢₙ is constant or gradually changes, operation of the source follower circuit including the transistor M₂ and the current source I_{b3} becomes dominant and also phase shifting in the entire buffer circuit is suppressed by the bias current supplied from the current source I_{b3} in each state of the input voltage Vᵢₙ. Therefore, the buffer circuit according to the present embodiment can be stably operated.

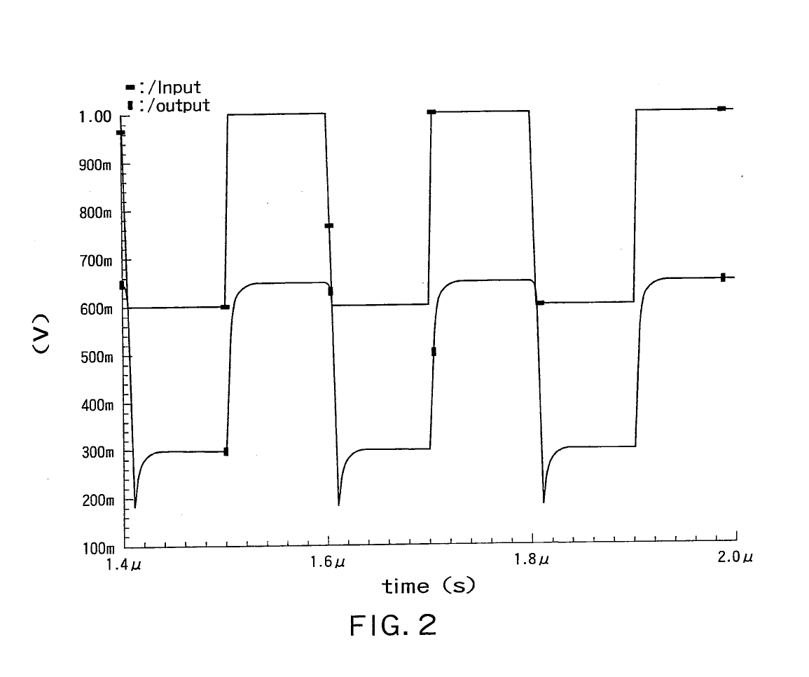

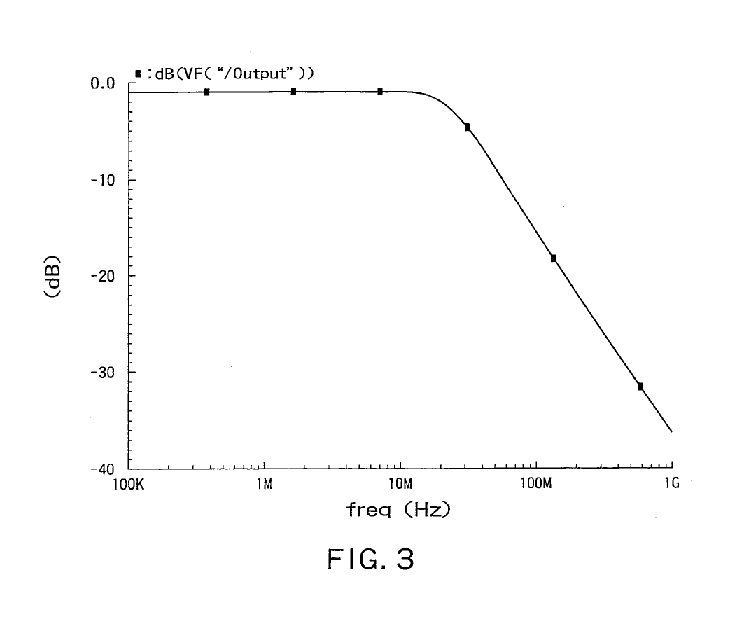

FIG. 2 is a diagram illustrating a simulation result of the buffer circuit according to the present embodiment based on a transient analysis. As illustrated in FIG. 2, it can be confirmed that no ringing occurs in the output voltage and the buffer circuit is stably operated. Further, FIG. 3 is a diagram illustrating a simulation result of the buffer circuit according to the present embodiment based on an AC analysis. As illustrated in FIG. 3, it can be confirmed that there is no peaking, which may indicate unstableness, formed in frequency characteristic.

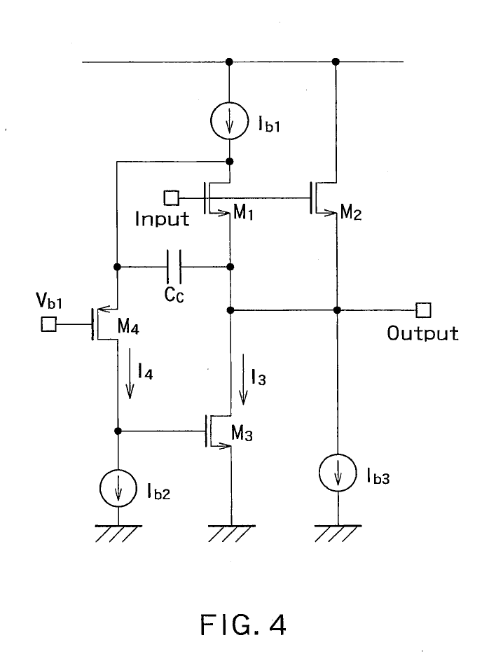

FIG. 4 is a circuit diagram illustrating a modified example of the present embodiment. As illustrated in FIG. 4, the buffer circuit includes capacitor Cc between the output terminal Output and the source terminal of the transistor M₄. With this configuration, change of the drain current I₃ and I₄ is suppressed in the case where the input voltage Vᵢₙ rapidly changes. Therefore, overshoot and undershoot of the output voltage Vₒᵤₜ can be suppressed.

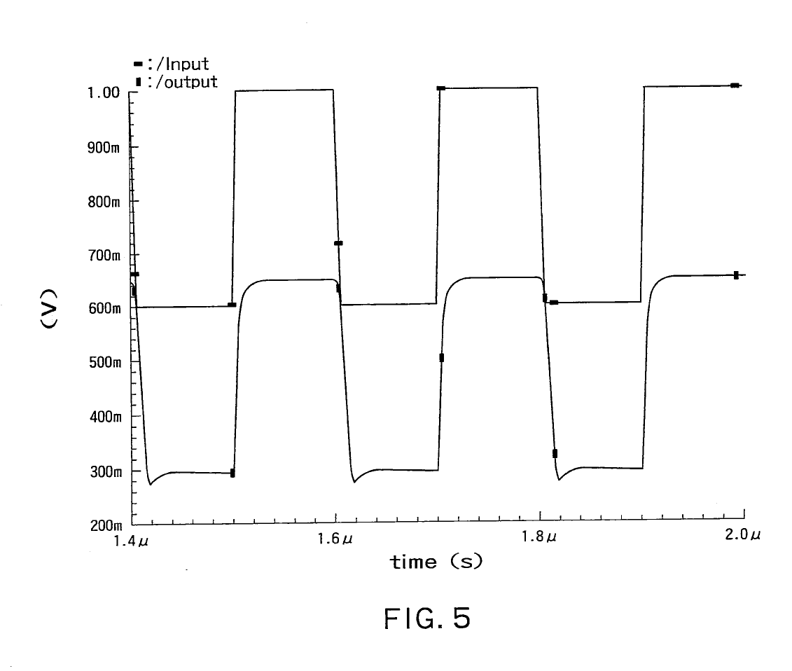

FIG. 5 is a diagram illustrating a simulation result of the buffer circuit in FIG. 4 based on the transient analysis. As illustrated in FIG. 4, it can be confirmed that no ringing occurs in the output voltage and the buffer circuit is stably operated. Also, it can be confirmed that undershoot of the output voltage observed at the time of fall of the input voltage in FIG. 2 is improved.

### Second Embodiment

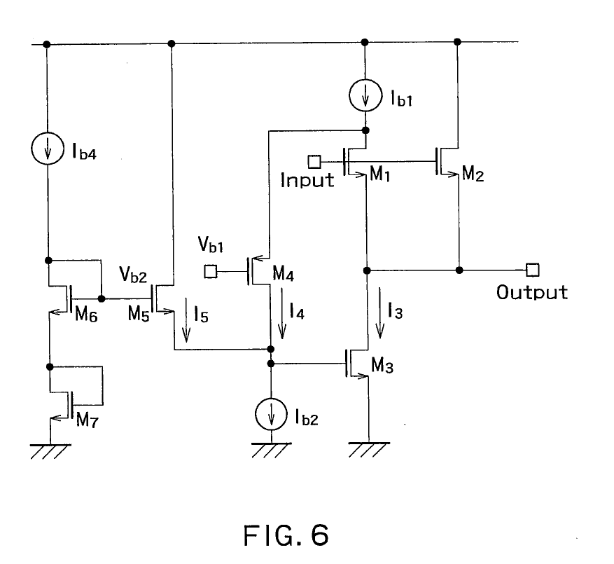

Next, a buffer circuit according to a second embodiment will be described with reference to FIGS. 6 to 8. Here, FIG. 6 is a circuit diagram illustrating the buffer circuit according to the second embodiment. As illustrated in FIG. 6, the buffer circuit includes an input terminal Input, an output terminal Output, transistors M₁ to M₇, and current sources I_{b1}, I_{b2}, I_{b4}. The transistors M₁ to M₄ and the current sources I_{b1} and I_{b2} have the same configuration as a first embodiment, and therefore description therefor is omitted here.

The transistor M₅ (fifth transistor) is an NMOS transistor, having a gate terminal (control terminal) connected to a gate terminal of the transistor M₆, a source terminal (first terminal) connected to a drain terminal of the transistor M₄, and a drain terminal (second terminal) connected to a power source. In the transistor M₅, predetermined bias voltage V_{b2} is applied and bias current I_{b5} corresponding to the bias voltage V_{b2} flows.

The transistors M₆ and M₇, and a current source I_{b4} form a bias circuit to apply the bias voltage V_{b2} to the transistor M₅. The transistors M₆ and M₇ are NMOS transistors and connected in a vertically stacked manner. In the case where the input voltage Vᵢₙ is substantially constant, source voltage of the transistor M₅ is gate voltage of the transistor M₃ and also substantially same as the gate voltage of the transistor M₇, namely, source voltage of the transistor M₆. Accordingly, in the transistor M₅, drain current corresponding to the current supplied from the current source I_{b4} flows. Meanwhile, a configuration of a bias circuit of the transistor M₅ can be optionally selected.

Next, operation according to the present embodiment will be described. When the input voltage Vᵢₙ is received from the input terminal Input, Vₒᵤₜ amplified by substantially single gain is output from the output terminal Output (Vᵢₙ≠Vₒᵤₜ). In the case where the input voltage Vᵢₙ is constant, the drain current I₄ and I₁ become constant as next: I₄=I_{b2}−I₅ and I₁=I_{b1}−(I_{b2}−I₅). And, change of the current flowing in a current control circuit including the transistors M₁, M₃, and M₄ becomes small. In this case, the transistor M₃ operates as a current source because the gate voltage of the transistor M₃ is substantially determined by the source voltage of the transistor M₅. Therefore, a source follower circuit including the transistor M₂ executes the same operation as a simple source follower in the related art, and the buffer circuit can be stably operated.

The state also becomes same in the case where the input voltage Vᵢₙ gradually changes, in which the drain current I₄ and become: I₄=I_{b2}−I₅, I₁=I_{b1}−(I_{b2}−I₅), because the voltage at the source terminal of the transistor M₁ changes following the input voltage Vᵢₙ, namely, the voltage at the gate terminal of the transistor M₁. Therefore, the buffer circuit can be stably operated.

More specifically, according to the present embodiment, in the case where the input voltage Vᵢₙ changes gradually, the drain current I₄ is decreased and drain current I₅ is increased. The voltage decrease at the gate terminal of the transistor M₃ corresponds to a changed amount of gate-source voltage at the transistor M₅ caused by the change of the drain current at the transistor M₅, and therefore becomes smaller than that of the first embodiment. In other words, according to present embodiment, impedance at the drain terminal of the transistor M₄ is 1/gm where gm is transconductance at the transistor M₅, and becomes lower than the case according to the first embodiment. Due to this, the voltage change at the gate terminal of the transistor M₃ caused by the change of the drain current I₄, namely, change of the drain current I₃ becomes smaller than the case according the first embodiment. Therefore, the buffer circuit can be stably operated.

Further, according to the present embodiment, in the case where the input voltage Vᵢₙ gradually falls, the drain current I₄ is increased and the drain current I₅ is decreased. However, the drain current I₅ never becomes zero. The voltage rise at the gate terminal of the transistor M₃ corresponds to a changed amount of the gate-source voltage at the transistor M₅ caused by the change of the drain current at the transistor M₅, and therefore becomes smaller than the first embodiment. In other words, according to the present embodiment, impedance at the drain terminal of the transistor M₄ is 1/gm where gm is transconductance at the transistor M₅, and becomes lower than the case according to the first embodiment. Due to this, voltage change at the gate terminal of the transistor M₃ caused by the change of the drain current I₄, namely, change of the drain current I₃ becomes smaller than the case according to the first embodiment. Therefore, the buffer circuit can be stably operated.

In contrast, in the case where the input voltage Vᵢₙ rapidly changes, the voltage at the source terminal of the transistor M₁ cannot instantaneously follow the change of the input voltage V. For example, in the case where the input voltage Vᵢₙ rapidly rises, the voltage at the source terminal of the transistor M₁ cannot rise following the change of the input voltage Vᵢₙ and therefore the gate-source voltage at the transistor M₁ rises. Due to this, the drain current I₁ is increased. When the drain current I₁ is increased, the drain current I₄ is decreased because the drain current is: I₄=I_{b1}−I₁. Since the drain current I₅ at the transistor M₅ is increased by the decreased amount of the drain current I₄, the gate-source voltage at the transistor M₅ becomes large. Due to this, the voltage at the gate terminal of the transistor M₃ falls and the drain current I₃ is decreased. The decreased drain current I₃ increases source current to the output terminal Output. Further, large current can be supplied from the transistor M₂ to the output terminal Output because the drain current of the transistor M₂ is not restricted. Thus, in the case where the input voltage Vᵢₙ rapidly changes, the source current is increased. The voltage at the source terminal of each of the transistors M₁ and M₂, which is the output voltage, rises slightly late following the rise of the input voltage Vᵢₙ.

Additionally, in the case where the input voltage Vᵢₙ rapidly rises, it is possible to set such that the drain current at the transistor M₄ becomes zero. In this case, the drain current I₁ and I₄ become as next: I₁=I_{b1}, I₄=0. And, the drain current I₃ is more decreased and the source current to the output terminal Output is more increased. When the change of the input voltage Vᵢₙ becomes small, rise of the input voltage Vᵢₙ becomes gradual and the voltage at the source terminal of the transistor M₁ rises following the change of the input voltage Vᵢₙ. Due to this, the current control circuit results in: I₄=I_{b2}−I₅, I₁=I_{b1}−(I_{b2}−I₅). Therefore, the buffer circuit can be stably operated.

Further, in the case where the input voltage Vᵢₙ rapidly falls, the voltage at the source terminal of the transistor M₁ cannot fall following the change of the input voltage Vᵢₙ, and therefore the gate-source voltage at the transistor M₁ falls. Due to this, the drain current I₁ is decreased. When the drain current I₁ is decreased, the drain current I₄ is increased because the drain current is: I₄=I_{b1}−I₁. When the increased drain current I₄ becomes larger than the bias current I_{b2}, the transistor M₅ is turned OFF, the voltage at the gate terminal of the transistor M₃ rises, and the drain current I₃ is increased. The increased drain current I₃ increases sink current from the output terminal Output.

When the change of the input voltage Vᵢₙ becomes small, the falling of the input voltage Vᵢₙ becomes gradual, and the voltage at the source terminal of the transistor M₁ falls following the change of the input voltage Vᵢₙ. Due to this, the current control circuit results in: I₄=I_{b2}−I₅, I₁=I_{b1}−(I_{b2}−I₅). Therefore, the buffer circuit can be stably operated.

As described above, according to the present embodiment, current driving capability can be improved by increasing the source current and the sink current of the output terminal Output by the current control circuit including the transistors M₁, M₃, and M₄. Additionally, in the case where the input voltage Vᵢₙ is constant or gradually changes, the change of the gate voltage at the transistor M₃ becomes small because of the transistor M₅, and the change of the drain current at the transistor M₃ becomes small, substantially constant. Due to this, operation of the source follower circuit by the transistor M₂ becomes dominant. Therefore, the buffer circuit according to the present embodiment can be stably operated.

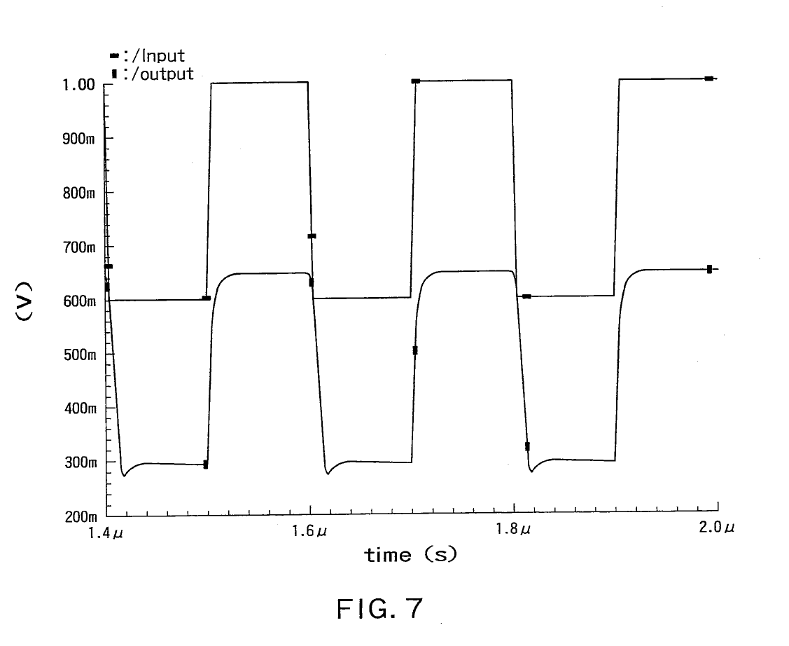

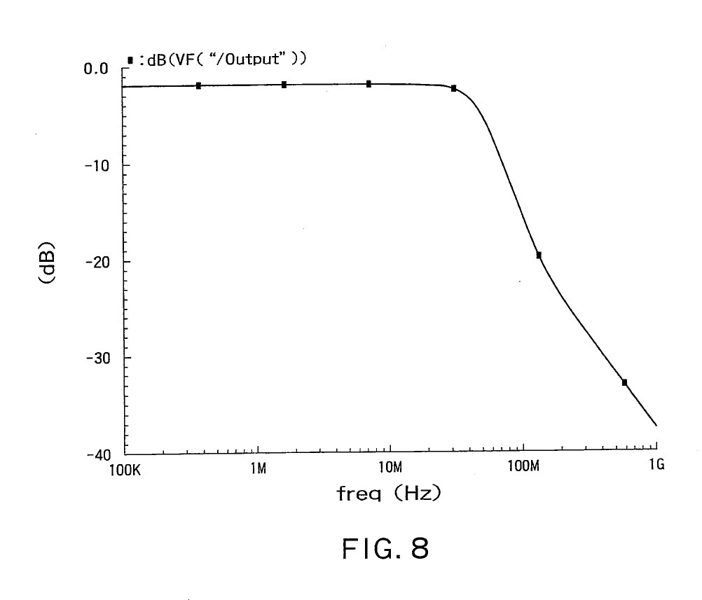

FIG. 7 is a diagram illustrating a simulation result of the buffer circuit according to the present embodiment based on a transient analysis. As illustrated in FIG. 7, it can be confirmed that no ringing occurs in the output voltage and the buffer circuit is stably operated. Additionally, FIG. 8 is a diagram illustrating a simulation result of the buffer circuit according to the present embodiment based on an AC analysis. As illustrated in FIG. 8, it can be confirmed that there is no peaking, which may indicate unstableness, formed in frequency characteristic. Meanwhile, the buffer circuit according to the present embodiment may include capacitor Cc between the output terminal Output and the source terminal of the transistor M₄. With this configuration, change of the drain current I₃ and I₄ is suppressed in the case where the input voltage Vᵢₙ rapidly changes. Therefore, overshoot and undershoot of the output voltage Vₒᵤₜ can be suppressed.

### Third Embodiment

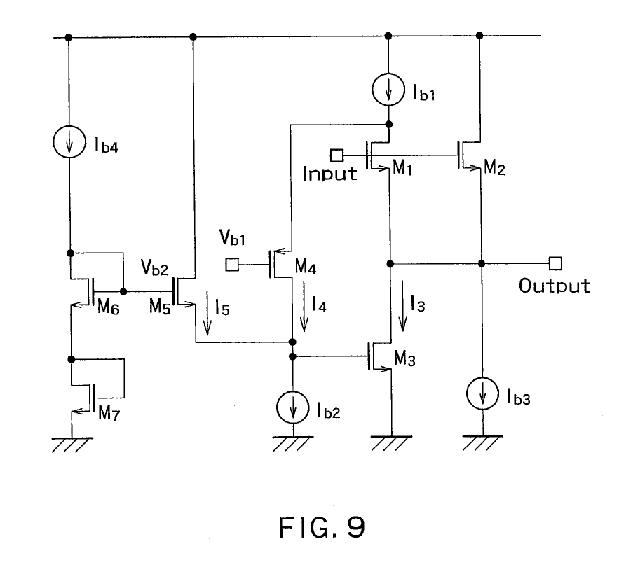

Next, a buffer circuit according to a third embodiment will be described with reference to FIGS. 9 to 12. Here, FIG. 9 is a circuit diagram illustrating the buffer circuit according to the third embodiment. As illustrated in FIG. 9, the buffer circuit according to the present embodiment is configured combining a first embodiment and a second embodiment, and includes an input terminal Input, an output terminal Output, transistors M₁ to M₇, and current sources I_{b1} to I_{b4}. The respective configurations and operation according to present embodiment are as described in the first embodiment and second embodiment, and therefore a description therefor is omitted here.

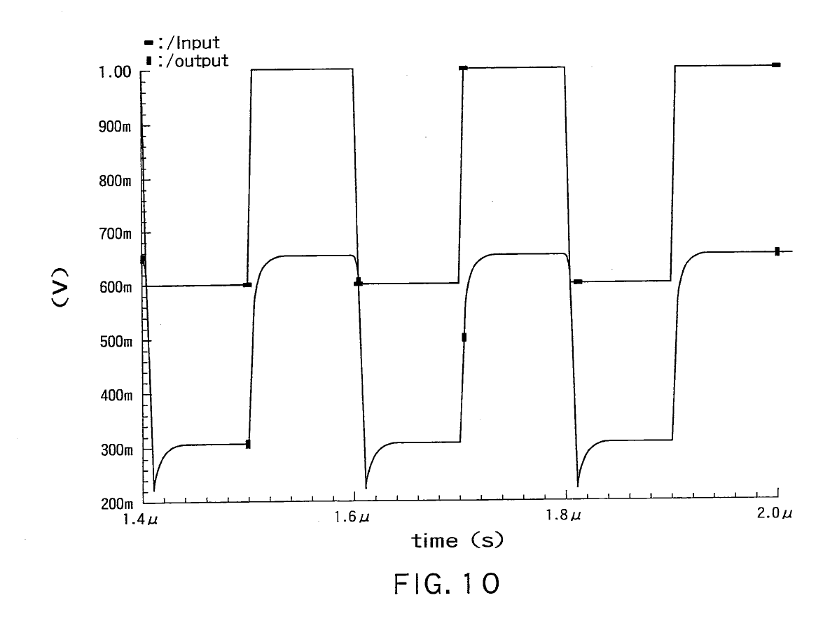

FIG. 10 is a diagram illustrating a simulation result of the buffer circuit according to the present embodiment based on a transient analysis. As illustrated in FIG. 10, it can be confirmed that no ringing occurs in the output voltage and the buffer circuit is stably operated.

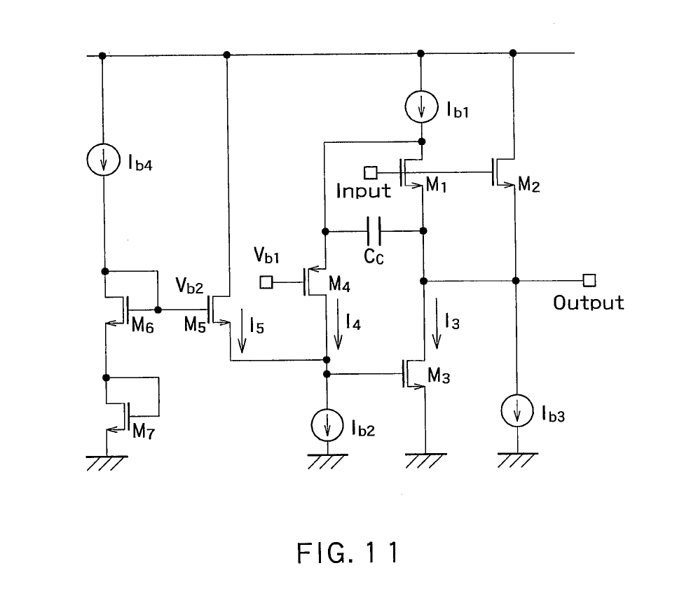

FIG. 11 is a circuit diagram illustrating a modified example of the present embodiment. As illustrated in FIG. 11, the buffer circuit includes capacitor Cc between the output terminal Output and the source terminal of the transistor M₄. With this configuration, change of the drain current I₃ and I₄ is suppressed in the case where the input voltage Vᵢₙ rapidly changes. Therefore, overshoot and undershoot of the output voltage Vₒᵤₜ can be suppressed.

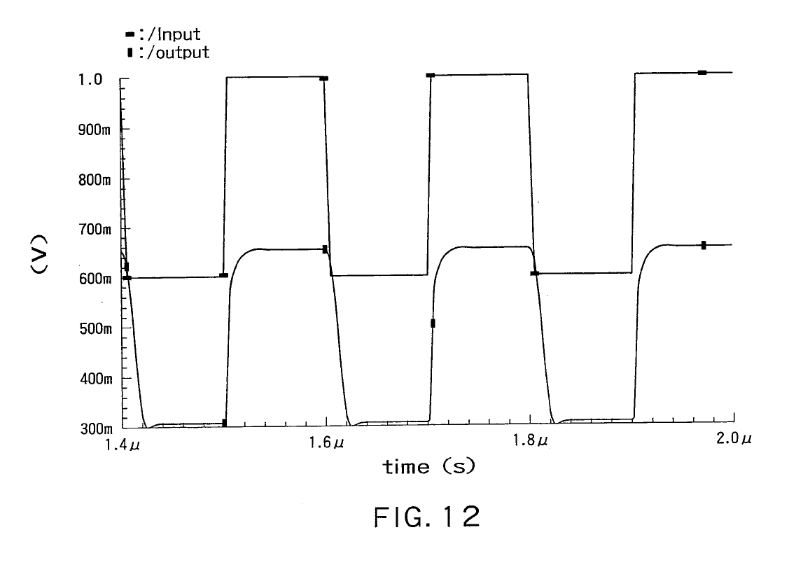

FIG. 12 is a diagram illustrating a simulation result of the buffer circuit in FIG. 11 based on the transient analysis. As illustrated in FIG. 12, it can be confirmed that no ringing occurs in the output voltage and the buffer circuit is stably operated. Also, it can be confirmed that undershoot of the output voltage observed at the time of fall of the input voltage in FIG. 12 is improved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A buffer circuit, comprising:
a first transistor having a control terminal connected to an input terminal, and a first terminal connected to an output terminal;
a second transistor having a control terminal connected to the input terminal, a first terminal connected to the output terminal, and a second terminal connected to a first power source;
a first current source connected between a second terminal of the first transistor and the first power source;
a third transistor having a first terminal connected to the output terminal;
a fourth transistor having a first terminal connected to a second terminal of the first transistor, a control terminal applied bias voltage, and a second terminal connected to a control terminal of the third transistor;
a second current source connected between the second terminal of the fourth transistor and a second power source; and
a third current source connected to the output terminal.

2. A buffer circuit, comprising:
a first transistor having a control terminal connected to an input terminal, and a first terminal connected to an output terminal;
a second transistor having a control terminal connected to the input terminal, a first terminal connected to the output terminal, and a second terminal connected to a first power source;
a first current source connected between a second terminal of the first transistor and the first power source;
a third transistor having a first terminal connected to the output terminal;
a fourth transistor having a first terminal connected to a second terminal of the first transistor, a control terminal applied bias voltage, and a second terminal connected to a control terminal of the third transistor;
a second current source connected between the second terminal of the fourth transistor and a second power source; and
a fifth transistor having a first terminal connected to the second terminal of the fourth transistor, and a control terminal applied bias voltage.

3. The buffer circuit according to claim 2, further comprising a third current source connected to the output terminal.

4. The buffer circuit according to claim 1, further comprising a capacitor between the output terminal and the first terminal of the fourth transistor.

5. The buffer circuit according to claim 1, current supplied from the first current source is larger than current supplied from the second current source.

6. The buffer circuit according to claim 1, wherein
the first terminals of the first transistor and the second transistor are source terminals or emitter terminals,
the second terminals of the first transistor and the second transistor, and the first terminal of the third transistor are drain terminals or collector terminals, and
the control terminals of the first transistor and the second transistor are gate terminals or base terminals.
